(19) United States
(12) Patent Application Publication
(10) Pub. No.: US 2014/0320746 A1
(43) Pub. Date: Oct. 30, 2014

(54) TELEVISION RECEIVER AND ELECTRONIC DEVICE

(71) Applicant: KABUSHIKI KAISHA TOSHIBA, Tokyo (JP)

(72) Inventors: Yuki Sato, Ome-shi (JP); Masashi Mikami, Ome-shi (JP)

(73) Assignee: KABUSHIKI KAISHA TOSHIBA, Tokyo (JP)

(21) Appl. No.: 14/176,297

(22) Filed: Feb. 10, 2014

(30) Foreign Application Priority Data
Apr. 26, 2013 (JP) 2013-094316

(51) Int. Cl. H04N 5/44; H05K 5/02

(52) U.S. Cl. CPC H04N 5/44; H05K 5/0217
USPC 348/725; 361/679.01

(57) ABSTRACT

According to one embodiment, a television receiver includes: a first housing; a component; a wall; and an electrical conductor. The component is exposed to the outside of the first housing with a gap between the component and the first housing. A wall is with a face facing the gap. The wall includes an opening. The gap is connected to inside of the first housing through the opening. The electrical conductor is on an inner face of the first housing.

### CROSS-REFERENCE TO RELATED APPLICATIONS

This application is based upon and claims the benefit of priority from Japanese Patent Application No. 2013-094316, filed Apr. 26, 2013, the entire contents of which are incorporated herein by reference.

### FIELD

Embodiments described herein relate generally to a television receiver and an electronic device.

### BACKGROUND

Conventionally, there has been known electronic devices such as a television receiver comprising a housing and a component exposed to an outside of the housing, such as a cover, a battery, and a touch panel.

In these types of electronic devices, for example, it is preferable that the influence of static electricity on the electronic devices be further reduced.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view of one example of a television receiver according to a first embodiment;

FIG. 2 is an exemplary side view of one example of the television receiver in the first embodiment;

FIG. 3 is an exemplary rear view of one example of a portion of the television receiver in the first embodiment;

FIG. 4 is an exemplary rear view of one example of a portion of the television receiver in a state in which a cover member is removed from a housing, in the first embodiment;

FIG. 5 is an exemplary cross-sectional view of a portion of a cross section taken along F5-F5 of FIG. 3, in the first embodiment;

FIG. 6 is an exemplary cross-sectional view of a portion of a cross section taken along F6-F6 of FIG. 4, in the first embodiment;

FIG. 7 is an exemplary perspective view of one example an electronic device according to a second embodiment;

FIG. 8 is an exemplary bottom plan view of one example of the electronic device in the second embodiment;

FIG. 9 is an exemplary schematic cross-sectional view of a portion of a cross section taken along F9-F9 of FIG. 8, in the second embodiment;

FIG. 10 is an exemplary bottom plan view of one example of a connector of a battery of the electronic device and a surrounding area thereof in a state in which the battery is installed in a housing of the electronic device, in the second embodiment;

FIG. 11 is an exemplary bottom plan view of one example of the connector of the battery of the electronic device and the surrounding area thereof in a state in which the battery is removed from the housing of the electronic device, in the second embodiment;

FIG. 12 is an exemplary view of one example of holes of the electronic device as seen from F12 of FIG. 11, in the second embodiment;

FIG. 13 is an exemplary view illustrating in details a portion of F13 portion of FIG. 9 in the second embodiment;

FIG. 14 is an exemplary cross-sectional view of a portion of an electronic device according to a third embodiment;

FIG. 15 is an exemplary perspective view of one example of an electronic device according to a fourth embodiment;

FIG. 16 is an exemplary cross-sectional view of one example of the electronic device in the fourth embodiment;

FIG. 17 is an exemplary front view of one example of a housing of the electronic device in the fourth embodiment;

FIG. 18 is an exemplary front view of one example of a portion of a double-faced adhesive tape of the electronic device in the fourth embodiment; and

FIG. 19 is an exemplary front view of one example of a portion of an array of pieces of a double-faced adhesive tape of an electronic device according to a fifth embodiment.

### DETAILED DESCRIPTION

In general, according to one embodiment, a television receiver comprises: a first housing; a component; a wall; and an electrical conductor. The component is exposed to the outside of the first housing with a gap between the component and the first housing. The wall is with a face facing the gap. The wall comprises an opening. The gap is connected to inside of the first housing through the opening. The electrical conductor is on an inner face of the first housing.

Exemplary embodiments described below comprise components similar to each other. Therefore, in the description below, common numerals are assigned to similar components, and overlapping explanation thereof will be partially omitted. The parts in each of the embodiments can be substituted with the corresponding parts in other embodiments. The structures and positions of the parts in each of the embodiments are the same as the corresponding parts in other embodiments, unless specified otherwise. Furthermore, in the drawings, directions (X direction, Y direction, and Z direction) are indicated for convenience. The X direction is a longitudinal direction with respect to a wall 3k of a housing 3A, a wall 3k of a housing 3B, or a wall 3k of a housing 3C viewed from the front (referred to as a plan view in the embodiments), the Y direction is a lateral direction with respect to the wall 3k of the housing 3A, the wall 3k of the housing 3B, or the wall 3k of the housing 3C viewed from the front (a plan view), and the Z direction is a thickness direction of the housing 3A, the housing 3B, or a housing 3C. The X direction, the Y direction, and the Z direction are orthogonal to one another.

The embodiments below will be described with examples in which an electronic device is achieved as a television receiver or a personal computer. The electronic devices in the embodiments, however, are not limited to these examples. Various types of electronic devices can be achieved in the embodiments such as a smart phone, a smart book, a mobile phone, a personal digital assistant (PDA), an image display apparatus, a video phone, an image display controller, an information storage device, for example.

### First Embodiment

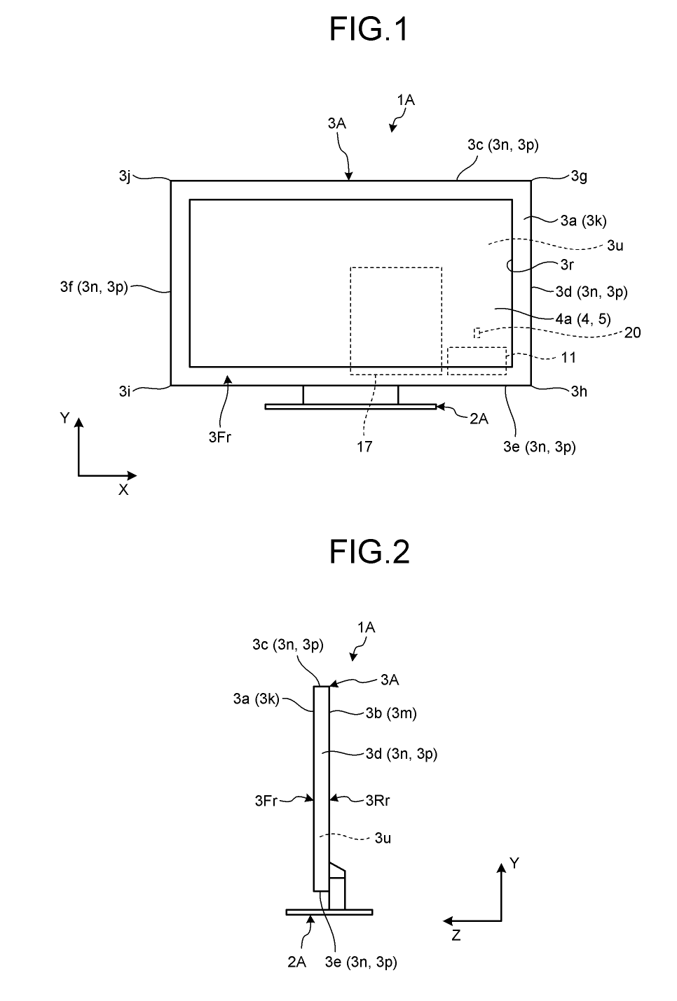

A television receiver 1A is an example of an electronic device according to the first embodiment. As illustrated in FIGS. 1 and 2, the television receiver 1A comprises a support 2A (a supporting part, a pedestal, a stand), and a housing 3A (a first housing), for example. Specifically, the support 2A is placed on a placement portion (a placement face, not illustrated) such as a desk, a rack, and a pedestal; and supports the housing 3A in a standing manner. The support 2A may support the housing 3A fixedly or movably (rotatably, slidably). Moving forms (rotationally moving forms) of the housing 3A with respect to the support 2A comprises a tilt, a swivel, and a pivot.

As illustrated in FIG. 1, the housing 3A has an appearance of a quadrangular shape (a rectangular shape as an example, in the embodiment) viewed from the front or the back, for example, in the first embodiment. As illustrated in FIG. 2, the housing 3A has a rectangular parallelepiped shape that is thin and flat in the front and back direction (the thickness direction of the housing 3A, Z direction). The housing 3A comprises a face 3a (a front face, a front face part) and a face 3b (a back face, a back face part, an outer face) located at the opposite side thereof. The face 3a and the face 3b are provided nearly side by side (in parallel as an example, in the embodiment). As illustrated in FIG. 1, the housing 3A comprises four ends 3c to 3f (sides, edges) and four corners 3g to 3j (pointed portions, bent portions, ends) viewed from the front. The ends 3c and 3e are examples of long sides. The ends 3d and 3f are examples of short sides. The housing 3A functions as an accommodation part that houses parts (not illustrated) and also as a supporting part that supports heavy objects (a display device 4 or other components), for example.

The housing 3A comprises the wall 3k (a part, a plate, a frame, a front wall, a front face wall, a top wall) comprising the face 3a, and a wall 3m (a part, a plate, a back wall, a rear face wall, a bottom wall) comprising the face 3b. The walls 3k and 3m each have a quadrangular shape (a rectangular shape as an example, in the embodiment). The wall 3k has a frame shape and the wall 3m has a plate shape. The housing 3A comprises four walls 3n (a part, a plate, a side wall, an end wall, a standing wall, a bridging portion) comprising each face 3p (a side face, a surrounding face) across the wall 3k and the wall 3m. An opening 3r in a quadrangular shape is provided on the wall 3k.

The housing 3A comprises a plurality of components (segments, members) combined with each other. The housing 3A comprises a first member 3Fr (a first part, a front side member, a cover, a bezel, a frame) comprising at least the wall 3k, and a second member 3Rr (a second part, a back side member, abase, a bottom, a plate, a cover) comprising at least the wall 3m. The wall 3n is structured as a portion of the second member 3Rr, for example, in the first embodiment. The housing 3A may comprise a third member (a third part, an intermediate member, an inner, a middle frame, a middle plate, not illustrated) separately from the first member 3Fr and the second member 3Rr. A portion of the third member can compose apart of the wall 3k, the wall 3m, or the wall 3n. The first member 3Fr and the third member are made of a metallic material or a synthetic resin material, for example. The second member 3Rr is made of a synthetic resin material (an electric insulator material), for example, in the first embodiment.

The display device 4 (a display module, a display, a panel, a display component) is housed in the housing 3A, for example in the first embodiment. Specifically, a display screen 4a located on the face 3a side of the display device 4 is exposed to the front (outside) of the housing 3A through the opening 3r. Users can visually recognize the display screen 4a from the front side of the display device 4 through the opening 3r. The display device 4 has an appearance of a quadrangular shape (a rectangular shape as an example, in the embodiment), viewed from the front of display device 4. The display device 4 has a rectangular parallelepiped shape that is thin and flat in the front and back direction. The display device 4 is a liquid crystal display (LCD), an organic electro-luminescent display (OELD), and a plasma display panel (PDP), for example.

An input operating panel 5 (e.g., a touch panel, a touch sensor, an operation face, an input operation part, an input receiving part) is provided on the front side (a front side, the wall 3k side) of the display device 4 (a display module, a display, a panel, a display part), for example, in the first embodiment. The input operating panel 5 is transparent and relatively thin and has a quadrangular shape. The input operating panel 5 covers the display screen 4a. An operator (e.g., a user) touches, presses, rubs the input operating panel 5 with his/her finger(s) or a stylus, for example, or moves his/her finger(s) or a stylus in the vicinity of the input operating panel 5, thereby executing input processing. The light emitted from the display screen 4a of the display device 4 penetrates through the input operating panel 5 and exits from the opening 3r of the wall 3k to the front (outside) of the housing 3A. The input operating panel 5 is an example of an operation part (an input part). The display device 4 and the input operating panel 5 are retained (supported) on either the first member 3Fr, the second member 3Rr, or the third member, with a retainer (a retaining component such as a screw, a metal fitting, and a part, not illustrated) and/or an adhesive (e.g., an adhesive agent, double-faced adhesive tape, not illustrated), for example, in the first embodiment.

As illustrated in FIG. 1, a module 11 (an electrical component, an electronic component, an attachment component, a component) is attached to the housing 3A, for example, in the first embodiment. The module 11 is a hard disk drive (HDD), for example, in the first embodiment. The module 11 is an example of a first electrical component. The module 11 may be an optical disk drive (ODD) or a solid state drive (SSD).

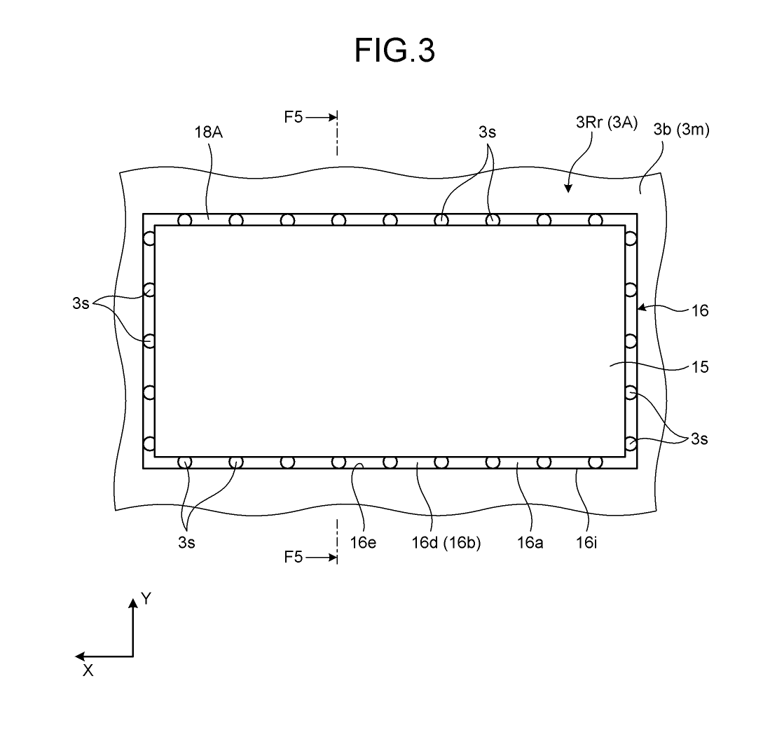

The module 11 is detachably attached to the housing 3A. As illustrated in FIGS. 3 to 5, the module 11 is housed in a holding portion 16 provided in the housing 3A, and coupled to the housing 3A with a not-illustrated coupling part (e.g., a screw). The module 11 held in the holding portion 16 is covered by a cover member 15, for example, illustrated in FIGS. 3 to 5.

The module 11 has an appearance of a flat rectangular parallelepiped shape, for example. The module 11 comprises a housing 11a and the circuit board 11b (a board, a controller, a control device). The housing 11a comprises a disk (not illustrated) and a head mechanism that writes on and reads from the disk, for example. The housing 11a, together with the disk and the head mechanism form a main body portion. The housing 11a can be made of a metallic material, for example. The circuit board 11b is fixed to the housing 11a while being exposed from the housing 11a. The circuit board 11b controls to drive the head mechanism. The circuit board 11b faces the cover member 15. The housing 11a and the circuit board 11b are exposed to an outside of the module 11. The housing 11a and the circuit board 11b are examples of conductive portions (conductive components, electrical components, components) in the first embodiment.

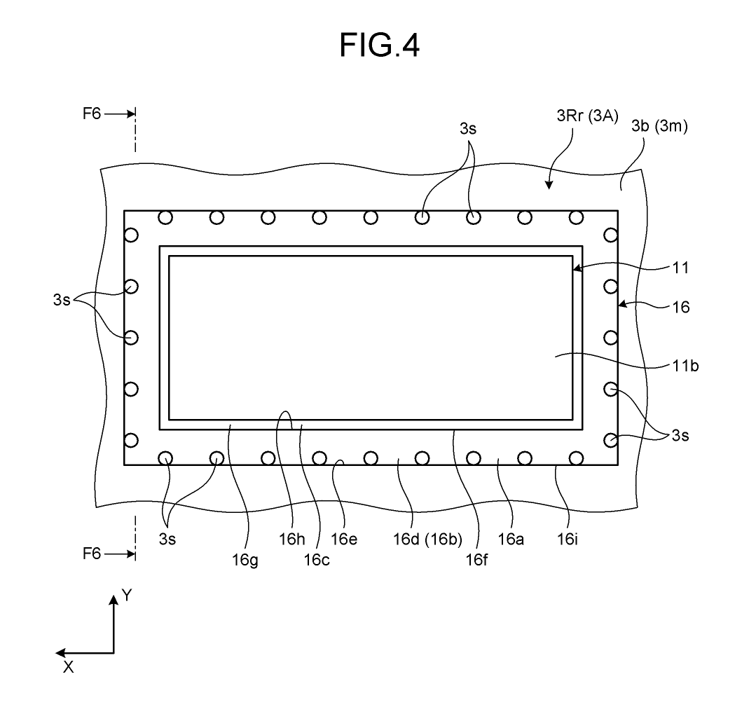

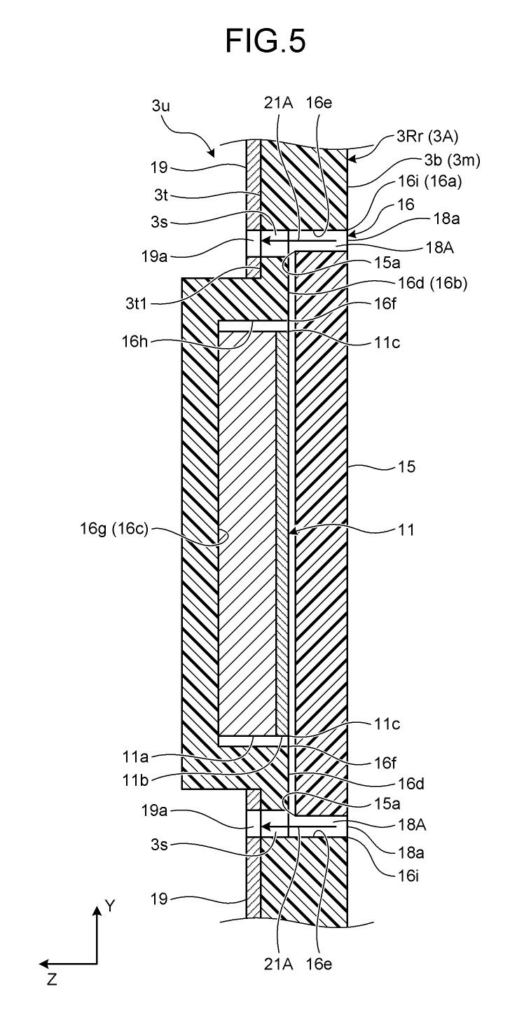

As illustrated in FIGS. 4 and 5, the holding portion 16 (a module holding portion, a housing accommodation holding portion, a recessed portion) is provided on the wall 3m (the face 3b) of the housing in a protruding manner, for example, in the first embodiment. The holding portion 16 opens to an outside of the housing 3A. An opening edge 16i (an opening end, an end) is an edge of an opening 16a of the holding portion 16 and has a quadrangular shape, for example, in the first embodiment.

The holding portion 16 is provided in a stepped and recessed manner, for example. More specifically, the holding portion 16 comprises a recessed portion 16b (a first recessed portion) comprising the opening edge 16i, and a recessed portion 16c (a second recessed portion) provided adjacent to the recessed portion 16b. The recessed portion 16b comprises a bottom face 16d (a face) and a square cylindrical face 16e (a cylindrical face) extending from an edge of the bottom face 16d to the opening edge 16i. The recessed portion 16c is provided on the bottom face 16d of the recessed portion 16b in a recessed manner. An opening edge 16f of the recessed portion 16c has a quadrangular shape, for example. The recessed portion 16c comprises a bottom face 16g (a face) and a square cylindrical face 16h (a cylindrical face) extending from an edge of the bottom face 16g to the opening edge 16f (the bottom face 16d). In the holding portion 16, the module 11 is housed in a state in which the housing 11a of the module 11 faces the bottom face 16g of the recessed portion 16c. The module 11 is fixed to the bottom face 16g separated from the face 16h, for example. Each of the bottom face 16d and the face 16e faces the cover member 15 with a gap 18A respectively interposed therebetween. That is, the bottom face 16d and the face 16e face the gap 18A, for example, in the first embodiment. For convenience of illustration, the gap 18A is magnified in FIG. 3 and another diagram.

In the first embodiment, the holding portion 16 configures a portion of the wall 3m that is an example of a wall provided on the housing 3A, comprising the bottom face 16d and the face 16e facing the gap 18A. The second member 3Rr is made of a synthetic resin material and is an example of a housing member provided with the gap 18A interposed between the second member 3Rr and the cover member 15.

As illustrated in FIGS. 3 and 5, the cover member 15 (a cover, plate-like member, a lid, a lid member, a plate, a wall, a member, a component) has a quadrangular plate shape, for example, in the first embodiment. The cover member 15 is located in the recessed portion 16b of the holding portion 16, for example. The cover member 15 blocks apart of the opening 16a and covers the module 11. The cover member 15 is detachably attached (coupled) to the wall 3m (e.g., the opening edge 16i of the holding portion 16) of the housing 3A with a tab or other hooking parts, for example. The cover member 15 is attached to the housing 3A (the bottom face 16d, the face 16e) with the gap 18A provided between the cover member 15 and the housing 3A, and exposed to the outside of the housing 3A. The gap 18A is partially provided between the housing 3A and the cover member 15, for example. The cover member 15 is an example of a component exposed to the outside of the housing 3A. The cover member 15 is made of a synthetic resin material (an electric insulator material), for example.

As illustrated in FIGS. 3 to 6, a through hole 3s is provided on the wall 3m (the holding portion 16), for example, in the first embodiment. A plurality of through holes 3s are provided, for example. The through holes 3s are provided around the module 11 with respective intervals provided therebetween. The through holes 3s open to the gap 18A and an inner portion 3u of the housing 3A (an inner space, a housing chamber) and communicate with the gap 18A and an inner portion 3u of the housing 3A. The through holes is opened with respect to the gap 18A at a position located on the way from an end 18a (FIG. 5) facing (approaching, exposed to) the outside of the housing 3A in the gap 18A to the housing 11a and the circuit board lib. The through holes 3s penetrates through the bottom face 16d (a first face) of the recessed portion 16b (a first face) provided on the wall 3m and an inner face 3t1 (a second face) of the wall 3m opposite the bottom face 16d, for example. The inner face 3t1 forms an inner face 3t of the housing 3A (the wall 3m). The cross-sectional face of each of the through holes 3s is a circle, for example. The cross-sectional face of each of the through holes may have other shapes such as a long-hole shape, an oval, and a polygon.

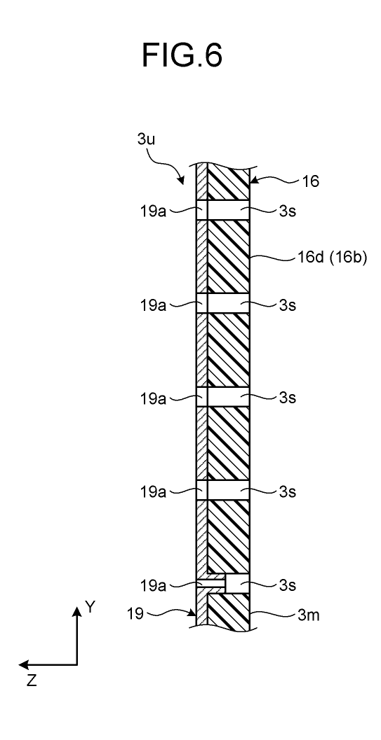

As illustrated in FIGS. 5 and 6, an electrical conductor 19 (a conductive layer, a conductive film, a metallic layer, a metallic film, a metallic portion) is provided on the inner face 3t of the housing 3A, the housing 3A comprising the wall 3m, for example, in the first embodiment. The electrical conductor 19 is provided in a layered manner (like a film), for example. The electrical conductor 19 contacts the inner face 3t. The electrical conductor 19 is provided to face the through holes 3s, for example. Through holes 19a are provided in the electrical conductor 19 and communicate with the through holes 3s. The electrical conductor 19 is provided partially on the inner face 3t, for example. The electrical conductor 19 may be provided entirely on the inner face 3t. The electrical conductor 19 is made of a conductive material and thus has electric conductivity. The conductive material is a metallic material such as aluminum, for example. The electrical conductor 19 is provided by sputtering, for example. As illustrated in FIG. 6, a portion of the electrical conductor 19 enters (is provide in) the through hole 3s, for example, in the first embodiment. This is because the material of the electrical conductor 19 has entered (come round) the through hole 3s during the sputtering, for example. In FIG. 6, a portion of the electrical conductor 19 enters one of the through holes 3s, for example, however, a portion of the electrical conductor 19 may enter all (two or more) of the through holes 3s. Furthermore, no portion of the electrical conductor 19 may enter the through holes 3s. The electrical conductor 19 may be made of a metallic sheet (a sheet), for example.

As illustrated in FIG. 5, the spatial distance between the end 18a of the gap 18A and the electrical conductor 19 is shorter than the spatial distance between the end 18a of the gap 18A and the circuit board 11b of the module 11, in the first embodiment. The spatial distance here is determined as follows, for example: the distance of the path extending from a certain position of the end 18a, through an edge 15a (an end) of the cover member 15 located on the bottom face 16d side of the recessed portion 16b, to an edge 11c on the cover member 15 side of the circuit board 11b. The spatial distance between the end 18a of the gap 18A and the electrical conductor 19 is also shorter than the spatial distance between the end 18a of the gap 18A and the housing 11a of the module 11, in the first embodiment.

The electrical conductor 19 is electrically connected to a ground terminal 20 of a power source terminal connected to an external power cable, for example. The television receiver 1A is operated by the electrical power supplied from the power source terminal. The power source terminal is exposed from the wall 3m, for example. The ground terminal 20 is an example of a reference electric-potential point (a ground portion). The electrical conductor 19 is electrically connected to the ground terminal 20 through a conductive member, for example.

A plurality of components (elements, electronic components, electrical components) such as a circuit board 17 are housed in the housing 3A, for example, in the first embodiment. The components mounted on the circuit board 17 (a board, a control board, a main board, an electrical component) configure at least a portion of a control circuit (not illustrated). The control circuit may comprise an image signal processing circuit, a tuner, a high-definition multimedia interface (HDMI) (registered trademark) signal processor, an audio video (AV) input port, a remote control signal receiver, a controller, a selector, an on-screen display interface, a storage (e.g., a read only memory (ROM), a random access memory (RAM), a hard disk drive (HDD)), an audio signal processing circuit, for example. The control circuit controls output of images (moving images and still images) on the display screen 4a of the display device 4, output of audio by a speaker (not illustrated), and emitting light by a light emitting diode (LED) (not illustrated). The display device 4, the speaker, and the LED are examples of output portions. The module 11 is electrically connected to the circuit board 17.

In the television receiver 1A configured as described above, the static electricity that has flowed from the outside of the television receiver 1A into the gap 18A (FIG. 5) moves along the gap 18A and through the through holes 3s to the electrical conductor 19, for example. In other words, the through holes 3s function as a guiding path (a leading path) guiding (leading) the static electricity to the electrical conductor 19, in the first embodiment. The static electricity here can move over the face 16e or the bottom face 16d. As described above, the static electricity that has flowed into the gap 18A moves through the through holes toward the electrical conductor 19, thereby preventing the static electricity from reaching the circuit board 11b or the housing 11a of the module 11 located ahead of the through holes 3s. An arrow 21A illustrated in FIG. 5 schematically represents an example of moving paths of the static electricity. The static electricity that has moved to the electrical conductor 19, then moves to the ground terminal 20, in the first embodiment.

As described above, the through holes 3s are provided on a face 16d facing the gap 18A between the housing 3A and the cover member 15 and communicate the gap 18A and the inner portion 3u of the housing 3A with each other; and the electrical conductor 19 is provided so as to be in contact with the inner face 3t of the housing 3A in the first embodiment. According to the first embodiment, therefore, the static electricity that has flowed into the gap 18A from the outside of the television receiver 1A moves to the electrical conductor 19 through the gap 18A and the through holes 3s, thereby preventing the static electricity from moving to the module 11, for example. According to the first embodiment, therefore, influence on the module 11 (a subject to be protected) by the static electricity can be reduced, for example.

The through holes 3s is opened with respect to the gap 18A at a position located on the way from the end 18a of the gap 18A facing the outside of the housing 3A to the housing 11a and the circuit board lib, in the first embodiment. The spatial distance between the end 18a of the gap 18A and the electrical conductor 19 is shorter than the spatial distance between the end 18a of the gap 18A and the circuit board lib (or the housing 11a) of the module 11. The first embodiment, therefore, can prevent the static electricity that has flowed into the gap 18A from moving to the circuit board 11b (or the housing 11a), for example.

The electrical conductor 19 is provided in a layered manner in the first embodiment. According to the first embodiment, therefore, the electrical conductor 19 can be provided in the housing 3A with a relatively smaller space.

The electrical conductor 19 is provided by sputtering in the first embodiment. According to the first embodiment, therefore, the electrical conductor 19 is coupled to the housing 3A in a relatively rigid manner.

The electrical conductor 19 is electrically connected to the ground terminal 20 in the first embodiment. According to the first embodiment, therefore, the static electricity moves from the electrical conductor 19 to the ground terminal 20, thereby preventing the static electricity from accumulating in the electrical conductor 19.

### Second Embodiment

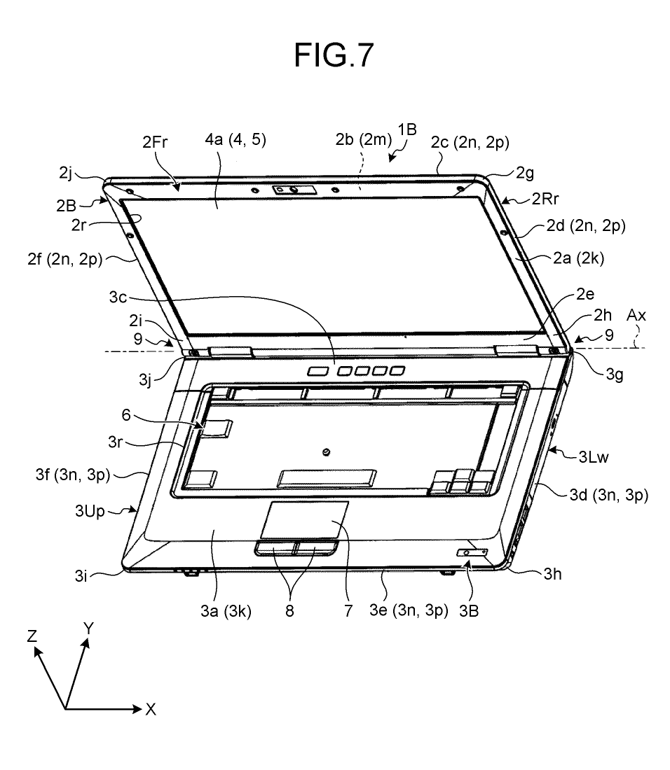

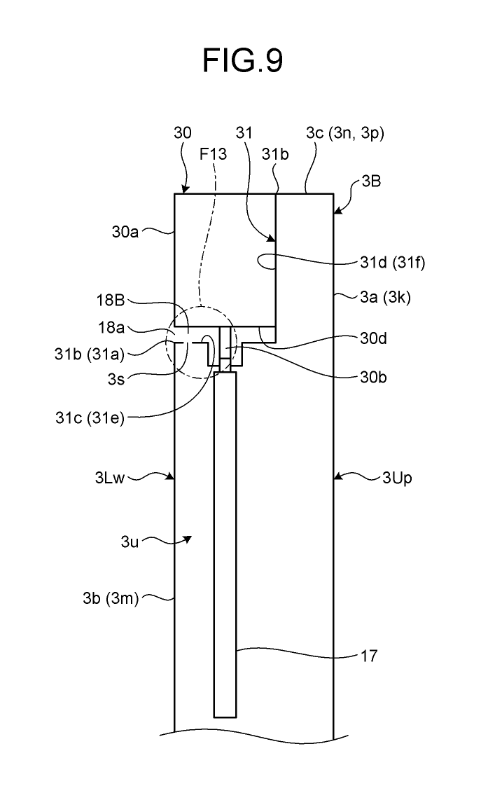

An electronic device 1B according to a second embodiment is a note book type personal computer in a “clam shell” shape. The electronic device 1B in the second embodiment has a function as a television receiver. As illustrated in FIG. 7, the electronic device 1B comprises the housing 3B and a housing 2B (another housing), for example, in the second embodiment. The housing 3B (a first part) houses the circuit board 17 (refer to FIG. 9). The housing 3B is an example of a first housing. The housing 2B (a second part) houses at least a part of the display device 4. In the housing 3B, a keyboard 6 (an input operation portion, an input receiver, an input portion), a touch pad 7 (an input operation portion, an input receiver, an input portion), click buttons 8 (an input operation portion, an input receiver, an input portion) are provided, for example.

The housing 3B and the housing 2B are coupled to each other in a rotationally movable manner, with a hinge 9 (a connection portion, a coupling portion, a rotationally moving support, a hinge mechanism, a connection mechanism, a coupling mechanism, a rotationally moving support mechanism). The housing 3B and the housing 2B are coupled to each other in a rotationally movable manner with the hinge 9, at least between a developed state as illustrated in FIG. 7 and a closed state (not illustrated). In the second embodiment, for example, the hinge 9 couples the housing 3B and the housing 2B in a rotationally moving manner around a rotationally moving axis Ax. The display screen 4a of the display device 4 is exposed from an opening 2r provided on a face 2a (a front side, a face portion) of the housing 2B. The keyboard 6, the touch pad 7, the click buttons 8 and so on are exposed to the face 3a (an upper face, a front face, a first face, a first face portion) of the housing 3B. In the closed state, the face 3a of the housing 3B and the face 2a of the housing 2B are overlapped with each other and the display screen 4a, the keyboard 6, the touch pad 7, and the click buttons 8 are hidden by the housing 3B and the housing 2B. In the developed state, the face 3a of the housing 3B and the face 2a of the housing 2B are exposed and the display screen 4a, the keyboard 6, the touch pad 7, and the click buttons 8 can be used (visually recognized or operated). In FIG. 7, only some keys of the keyboard 6 are illustrated.

As illustrated in FIG. 7, the housing 2B has an appearance of a quadrangular shape (a rectangular shape as an example, in the embodiment) viewed from the front or the back, for example, in the second embodiment. As illustrated in FIG. 2, the housing 2B has a rectangular parallelepiped shape that is thin and flat in the front and back direction (the thickness direction of the housing 2B). The housing 2B comprises a face 2a and a face 2b (a back face, a back face portion) located opposite the face 2a. The face 2a and the face 2b are provided nearly side by side (in parallel as an example, in the embodiment). The housing 2B comprises four ends 2c to 2f (sides, edges) and four corners 2g to 2j (pointed portions, bent portions, ends) viewed from the front. The ends 2c and 2e are examples of long sides. The ends 2d and 2f are examples of short sides.

The housing 2B comprises the wall 2k (a part, a plate, a frame, a front wall, a front face wall, a top wall) comprising the face 2a, and a wall 2m (a part, a plate, a back wall, a rear face wall, a bottom wall) comprising the face 2b. The walls 2k and 2m are provided respectively in a quadrangular shape (a rectangular shape as an example, in the embodiment). The wall 2k has a frame shape and the wall 2m has a plate shape. The housing 2B comprises four walls 2n (a part, a plate, a side wall, an end wall, a standing wall, a surrounding part) each comprising a face 2p (a side face, a surrounding face) across the wall 2k and the wall 2m. An opening 2r in a quadrangular shape is provided on the wall 2k.

The housing 2B comprises a plurality of components (segments, members) combined with each other. The housing 2B comprises a first member 2Fr (a first part, a front side member, a cover, a bezel, a frame) comprising at least the wall 2k, and a second member 2Rr (a second part, a back side member, abase, a bottom, a plate, a cover) comprising at least the wall 2m. The wall 2n is structured as a part of the second member 2Rr, for example, in the second embodiment. The first member 2Fr and the second member 2Rr are made of a metallic material or a synthetic resin material, for example.

The display device 4 (a display module, a display, a panel, a display component), for example, is housed in the housing 2B in the second embodiment. Specifically, a display screen 4a located on the face 2a side of the display device 4 is exposed to the front (outside) of the housing 2B through the opening 2r. Users can visually recognize the display screen 4a from the front side of the display device 4 through the opening 2r. The display device 4 has an appearance of a quadrangular shape (a rectangular shape as an example, in the embodiment), viewed from the front of display device 4. The display device 4 has a rectangular parallelepiped shape that is thin and flat in the front and back direction. The display device 4 is a liquid crystal display (LCD), an organic electro-luminescent display (OELD), and a plasma display panel (PDP), for example.

An input operating panel 5 (e.g., a touch panel, a touch sensor, an operation face, an input operation portion, an input receiver) is provided on the front side (a front side, the wall 2k side) of the display device 4 in the second embodiment, for example. The input operating panel 5 is transparent and relatively thin and has a quadrangular shape. The input operating panel 5 covers the display screen 4a. An operator (e.g., a user) touches, presses, rubs the input operating panel 5 with his/her finger(s) or a stylus, for example, or moves his/her finger(s) or a stylus in the vicinity of the input operating panel 5, thereby executing input processing. The light emitted from the display screen 4a of the display device 4 penetrates through the input operating panel 5 and exits from the opening 2r of the wall 2k to the front (outside) of the housing 2B. The input operating panel 5 is an example of an operation part (an input part). The display device 4 and the input operating panel 5 are retained (supported) on either the first member 2Fr or the second member 2Rr with a retainer (a retaining part such as a screw, a metal fitting, and a part, not illustrated) or an adhesive part (e.g., an adhesive agent, a double-faced adhesive tape, not illustrated), for example, in the second embodiment.

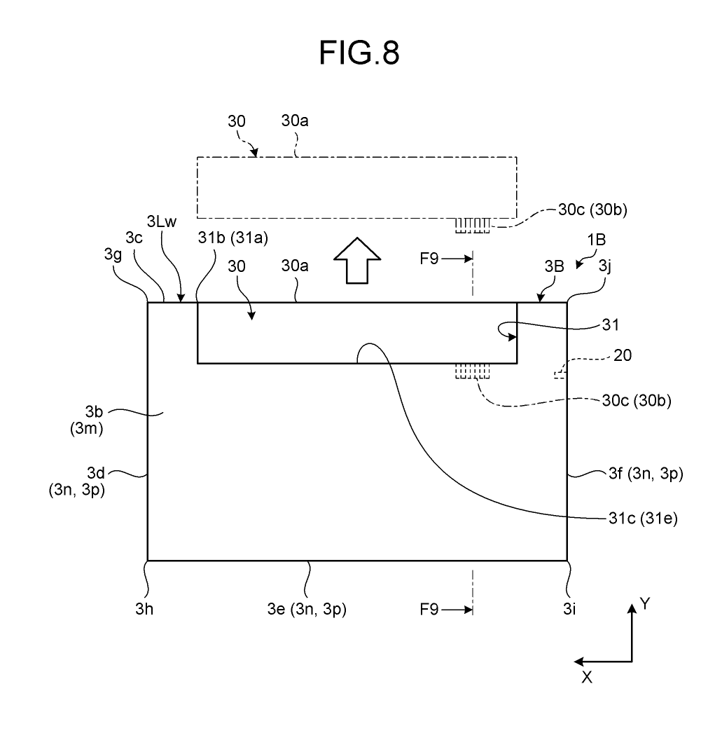

As illustrated in FIGS. 7 and 8, the housing 3B has an appearance of a quadrangular shape (a rectangular shape as an example, in the embodiment) viewed from the front or the back, for example, in the second embodiment. The housing 3B has a rectangular parallelepiped shape that is thin and flat in the front and back direction (the thickness direction of the housing 3B, Z direction), for example, in the second embodiment. The housing 3B comprises a face 3a (an upper face, a front face portion) and a face 3b (a lower face, a back face portion) located opposite the face 3a. The face 3a and the face 3b are provided nearly side by side (in parallel as an example, in the embodiment). The housing 3B comprises four ends 3c to 3f (sides, edges) and four corners 3g to 3j (pointed portions, bent portions, ends) viewed from the front. The ends 3c and 3e are examples of long sides. The ends 3d and 3f are examples of short sides. The housing 3B functions as an holding portion that holds components such as a circuit board 17, for example and also as a supporting portion that supports heavy objects (components and the like).

The housing 3B comprises the wall 3k (a part, a plate, a frame, an upper wall, a front face wall, a top wall) comprising the face 3a, and a wall 3m (a part, a plate, a lower wall, a rear face wall, a bottom wall) comprising the face 3b. The walls 3k and 3m are provided respectively in a quadrangular shape (a rectangular shape as an example, in the embodiment). The wall 3k has a frame shape and the wall 3m has a plate shape. The housing 3B comprises four walls 3n (a part, a plate, a side wall, an end wall, a standing wall, a surrounding part) each comprising a face 3p (a side face, a surrounding face) across the wall 3k and the wall 3m. An opening 3r in a quadrangular shape is provided on the wall 3k.

The housing 3B comprises a plurality of components (segments, members) combined with each other. The housing 3B comprises a first member 3Up (a first part, an upper side member, a cover, a mask, a plate) comprising at least the wall 3k, and a second member 3Lw (a second part, a lower side member, a base, a bottom, a plate, a cover) comprising at least the wall 3m. The wall 3n is configured as a portion of the second member 3Lw, for example, in the second embodiment. The housing 3B may comprise a third member (a third part, an intermediate member, an inner, a middle frame, a middle plate, not illustrated) provided separately from the first member 3Up and the second member 3Lw, and located therebetween. A portion of the third member can compose a portion of the wall 3k, the wall 3m, or the wall 3n, for example, in the second embodiment. The first member 3Up and the third member are made of a metallic material or a synthetic resin material, for example. The second member 3Lw is made of a synthetic resin material (an electric insulator material), for example, in the second embodiment.

As illustrated in FIG. 9, at least one circuit board 17 (a board, a control board, a main board, an electrical component) is housed in the housing 3B, for example, in the second embodiment. The circuit board 17 is provided side by side (in parallel as an example, in the embodiment) with the keyboard 6 (refer to FIG. 7).

As illustrated in FIG. 8, a battery 30 (an electrical component, an electronic component, an attachment component, a component) is installed in (coupled to) the housing 3B, for example, in the second embodiment. The battery 30 may be a lithium-ion secondary battery, for example. The battery 30 is an example of a first electrical component coupled to the housing 3B.

As illustrated in FIG. 8, the battery 30 is removably installed in the housing 3B. As illustrated in FIGS. 8 and 9, the battery 30 is housed in a holding portion 31 provided in the housing 3B. The battery 30 is exposed from the housing 3B.

The battery 30 comprises a housing 30a and a connector 30b (a terminal, an electrical component) protruding from the housing 30a, for example. The housing 30a has an appearance of a nearly flat rectangular parallelepiped shape, for example.

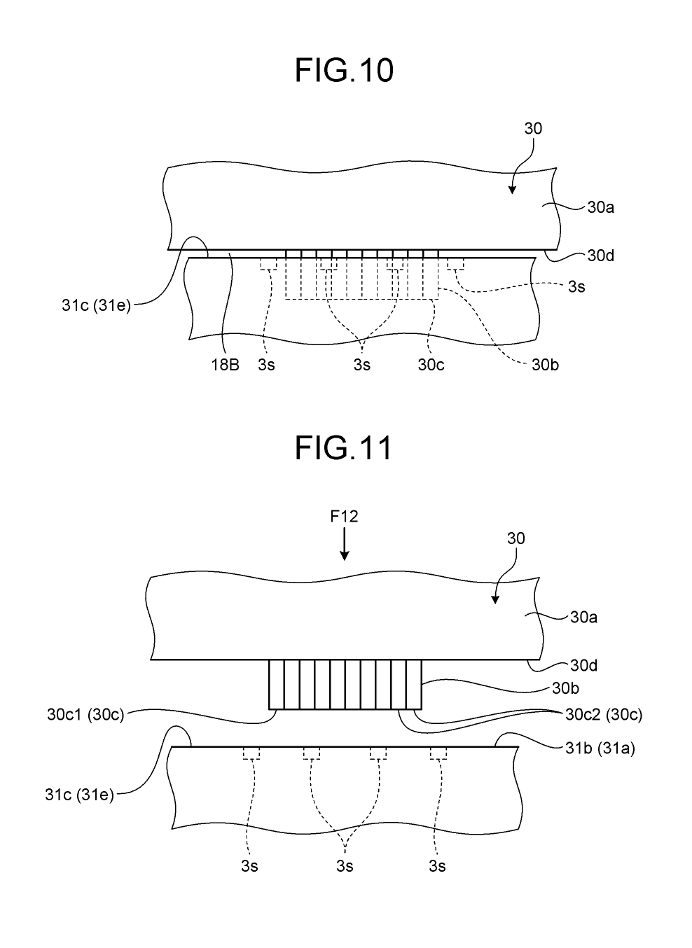

The housing 30a houses an electric storage portion and a circuit board, for example. The housing 30a is detachably attached (coupled) to the housing 3B with a tab or other hooking portions, for example. The housing 30a is exposed to the outside of the housing 3B. As illustrated in FIGS. 9 and 10, the housing 30a is attached to the housing 3B with a gap 18B interposed between the housing 30a and the housing 3B. The housing 30a is made of a synthetic resin material (an electric insulator material), for example. The housing 30a is an example of a second housing (a component). The connector 30b is fixed to the housing 30a and coupled to the housing 3B via the housing 30a. For convenience of illustration, the gap 18B is magnified in FIG. 9 and another diagram.

As illustrated in FIGS. 9 to 11, the connector 30b is protruded from a face 30d (a side face) of the housing 30a. The connector 30b comprises a plurality of pins 30c (terminals). The pins 30c are arranged side by side to each other with respective intervals provided therebetween. Examples of the pins 30c include pins for communication and pins for electricity. One of the pins 30c is a ground pin (hereinafter, also referred to as a ground pin 30c1), for example, in the second embodiment. A plurality of pins 30c2, other than the ground pin 30c1 out of the pins 30c, are provided. The connector 30b is electrically connected to the circuit board 17. More specifically, the connector 30b is connected to a connector mounted on the circuit board 17 and thus electrically connected to the circuit board 17. The connector 30b is exposed to the outside of the battery 30. The connector 30b is an example of conductive portions (conductive components, electrical components, components).

As illustrated in FIGS. 8 and 9, the holding portion 31 (a module holding portion, a housing holding portion, a recessed portion) is provided in a recessed manner across the wall 3m (the face 3b) and the wall 3n (e.g., the wall 3n on the back side) of the housing 3B and opens to the outside of the housing 3B, for example, in the second embodiment. An opening edge 31b (an opening end, an end) that is an edge of an opening 31a of the holding portion 31 is provided across the wall 3m and the wall 3n, in the second embodiment.

The holding portion 31 comprises a face 31c extended from the wall 3m and a face 31d extended from the wall 3n, for example. The holding portion 31 also comprises a wall 31e extended from the wall 3m and comprising the face 31c, and a face 31f extended from the wall 3n and comprising the face 31d. The battery 30 (the housing 30a) is housed in the holding portion 31 in a state in which the face 30d of the battery 30 faces the face 31c with the gap 18B. That is to say, the face 31c faces the face 30d of the battery 30 (the housing 30a) with the gap 18B interposed between the face 31c and the face 30d. In the second embodiment, the wall 31e is an example of a wall provided on the housing 3B and comprising the face 31c facing the gap 18B. In the second embodiment, the second member 3Lw is an example of a housing member made of a synthetic resin material and provided with the gap 18B interposed between itself and the housing 30a.

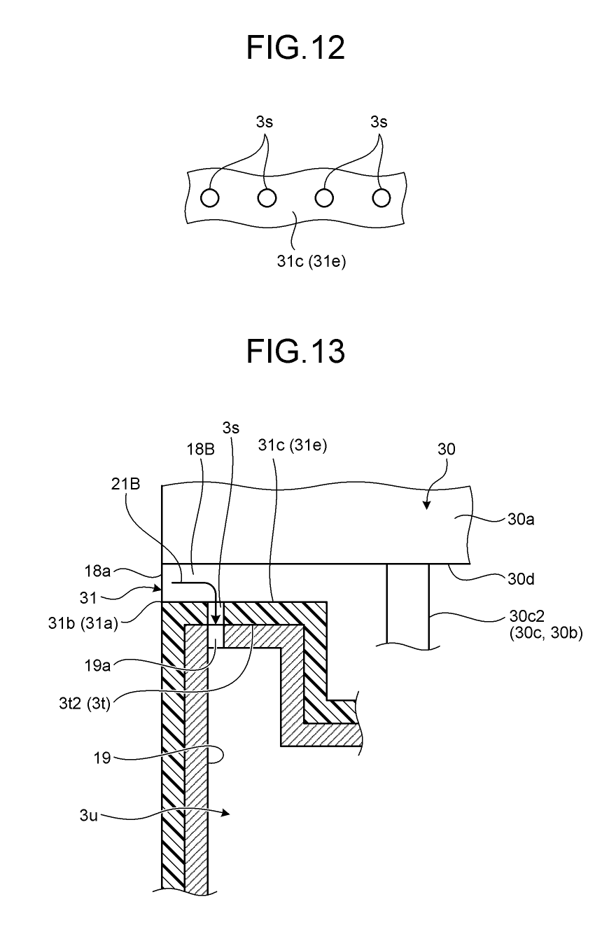

As illustrated in FIGS. 9 to 13, the through hole 3s is provided on the wall 31e (the holding portion 31), for example, in the second embodiment. A plurality of through holes 3s are provided, for example. The through holes 3s are provided with respective intervals provided therebetween. The through holes 3s open to the gap 18B and an inner portion 3u of the housing 3B (an inner space, a housing chamber, a chamber) and communicate with the gap 18B and the inner portion 3u of the housing 3B. The through holes is opened with respect to the gap 18B at a position located on the way from an end 18a facing (approaching, exposed to) the outside of the housing 3B in the gap 18B to the connector 30b. The through holes 3s penetrate through the face 31c of the wall 31e and a face 3t2 (an inner face) opposite the face 31c on the wall 31e, for example. The inner face 3t2 forms an inner face 3t of the housing 3B. The cross-sectional face of each of the through holes 3s is a circle, for example. The cross-sectional face of each of the through holes may have other shapes such as a long-hole shape, an oval, and a polygon.

As illustrated in FIG. 13, the electrical conductor 19 (a conductive layer, a conductive film, a metallic layer, a metallic film, a metallic portion) is provided on the inner face 3t of the housing 3B comprising the inner face 3t2 of the wall 3m, for example, in the second embodiment. The electrical conductor 19 is provided in a layered manner (like a film), for example. The electrical conductor 19 contacts the inner face 3t of the housing 3B. The electrical conductor 19 is provided to face the through hole 3s, for example. A through hole 19a is provided in the electrical conductor 19, and the through hole 19a communicates with the through hole 3s. The electrical conductor 19 is provided partially on the inner face 3t, for example. The electrical conductor 19 may be provided entirely on the inner face 3t. The electrical conductor 19 is made of a conductive material and thus has electric conductivity. The conductive material is a metallic material such as aluminum, for example. The electrical conductor 19 is provided by sputtering, for example. The electrical conductor 19 may be made of a metallic sheet (a sheet).

The spatial distance between the end 18a of the gap 18B and the electrical conductor 19 is shorter than the spatial distance between the end 18a of the gap 18B and the connector 30b (e.g., the pin 30c2 used for communication) in the second embodiment.

The electrical conductor 19 is electrically connected to the ground terminal 20 (FIG. 8) of the power source terminal connected to an external power cable, for example. The ground terminal 20 is an example of the reference electric-potential point (a ground). The electrical conductor 19 is electrically connected to the ground terminal 20 through a conductive member, for example. In the second embodiment, the electrical conductor 19 is also electrically connected to the ground pin 30c1 of the connector 30b. The ground pin 30c1 is an example of a reference electric-potential point (ground). The electrical conductor 19 can be electrically connected to the ground pin 30c1 through a conductive member, for example. If the power source terminal is not connected to the external power cable, the static electricity moves to the ground pin 30c1, in the second embodiment.

A plurality of components can be mounted on the circuit board 17, such as a central processing module (CPU), a graphics controller, power supply circuit parts, a platform controller hub (PCH), a memory slot connector, a liquid crystal display (LCD) connector, an input/output (I/O) connector, a power supply coil, an element, and a connector, for example, in the second embodiment. The control circuit may comprise an image signal processing circuit, a tuner, a high-definition multimedia interface (HDMI) (registered trademark) signal processor, an audio video (AV) input port, a remote control signal receiver, a controller, a selector, an on-screen display interface, a storage (e.g., a read only memory (ROM), a random access memory (RAM), a hard disk drive (HDD), a solid state drive (SSD)), an audio signal processing circuit. The control circuit controls output of images (moving images and still images) on the display screen 4a of the display device 4, output of audio by the speaker (not illustrated), and light emitted by the light emitting diode (LED) (not illustrated). The display device 4, the speaker, and the LED are examples of output parts. The circuit board 17 is an example of a second electrical component, in the second embodiment.

In the electronic device 1B configured as described above, the static electricity that has flowed from the outside of the electronic device 1B into the gap 18B moves along the gap 18B and through the through holes 3s to the electrical conductor 19, for example. In other words, the through holes 3s function as a guiding path (a leading path) guiding (leading) the static electricity to the electrical conductor 19, in the second embodiment. The static electricity here can move over the face 31c. The static electricity moves through the through holes 3s toward the electrical conductor 19, thereby preventing the static electricity from reaching the connector 30b located ahead of the through holes 3s. An arrow 21B illustrated in FIG. 13 schematically represents an example of moving paths of the static electricity. The static electricity that has moved to the electrical conductor 19, then moves to the ground terminal 20 or the earth pin 30c1, in the second embodiment.

As described above, the through holes 3s are provided on the face 31c facing the gap 18B between the housing 3B and the housing 30a of the battery 30, and communicate the gap 18B and the inner portion 3u of the housing 3B with each other; and the electrical conductor 19 is provided to be in contact with the inner face 3t of the housing 3B in the second embodiment. According to the second embodiment, therefore, the static electricity that has flowed into the gap 18B from the outside of the electronic device 1B moves to the electrical conductor 19 through the gap 18B and the through holes 3s, thereby preventing the static electricity from moving to the connector 30b (the pin 30c2), for example. The second embodiment, therefore, can prevent the static electricity from moving to the circuit board 17 through the connector 30b (the pin 30c2), thereby reducing influence on the circuit board 17 (a subject to be protected) by the static electricity, for example.

The through holes 3s is opened with respect to the gap 18B at a position located on the way from the end 18a of the gap 18B facing the outside of the housing 3B to the connector 30b (the pin 30c2), in the second embodiment. The spatial distance between the end 18a of the gap 18B and the electrical conductor 19 is shorter than the spatial distance between the end 18a of the gap 18B and the connector 30b (the pin 30c2). The second embodiment, therefore, can prevent the static electricity that has flowed into the gap 18B from moving to the connector 30b (the pin 30c2), for example.

The electrical conductor 19 is electrically connected to the ground terminal 20 and the ground pin 30c1 in the second embodiment. According to the second embodiment, therefore, the static electricity moves from the electrical conductor 19 to the ground terminal 20 and the ground pin 30c1, thereby preventing the static electricity from accumulating in the electrical conductor 19.

### Third Embodiment

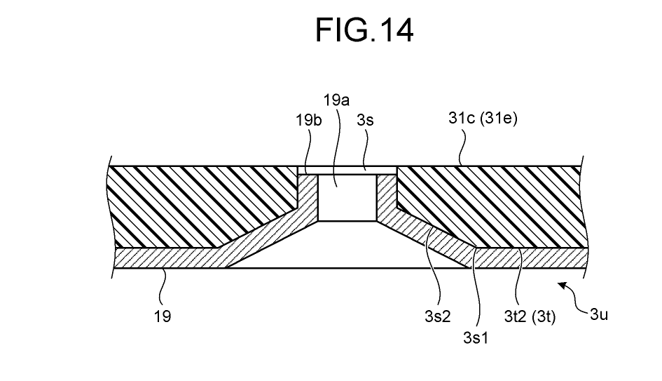

As illustrated in FIG. 14, the through holes 3s and the electrical conductor 19 of the electronic device 1B are different from the second embodiment, for example, in the third embodiment. Other parts of the electronic device 1B in the third embodiment are the same as the second embodiment.

The through hole 3s comprises an enlarged diameter portion 3s2 (a part). The enlarged diameter portion 3s2 is a portion with a diameter that increases toward an end 3s1 on the inner portion 3u side of the housing 3B in the through hole 3s. The electrical conductor 19 is provided on the inner face 3t of the housing 3B in the same manner as the second embodiment, and a portion 19b of the electrical conductor 19 is provided (extended) in the through hole 3s. In the third embodiment, for example, the electrical conductor 19 is provided from the end 3s1 of the through hole 3s to the middle of the through hole 3s. The electrical conductor 19 may be provided so as to extend to the face 31c of the through hole 3s through the through hole 3s. The electrical conductor 19 is provided by sputtering in the same manner as the second embodiment. The enlarged diameter portion 3s2 of the through hole 3s in the third embodiment facilitates the material composing the electrical conductor 19 to enter the through hole 3s while the sputtering is performed.

According to the embodiment described above, similar advantageous effects in the fourth embodiment can be achieved. Additionally, in the third embodiment, there is an advantage in that the electrical conductor 19 provided in the through hole 3s facilitates the static electricity to more readily move to the electrical conductor 19.

### Fourth Embodiment

An electronic device 1C according to a fourth embodiment serves as, for example, a personal computer, a television receiver, a smart phone, a smart book, a mobile phone, and a personal digital assistant (PDA), with a slate-type or a tablet-type display comprising a function of a software keyboard.

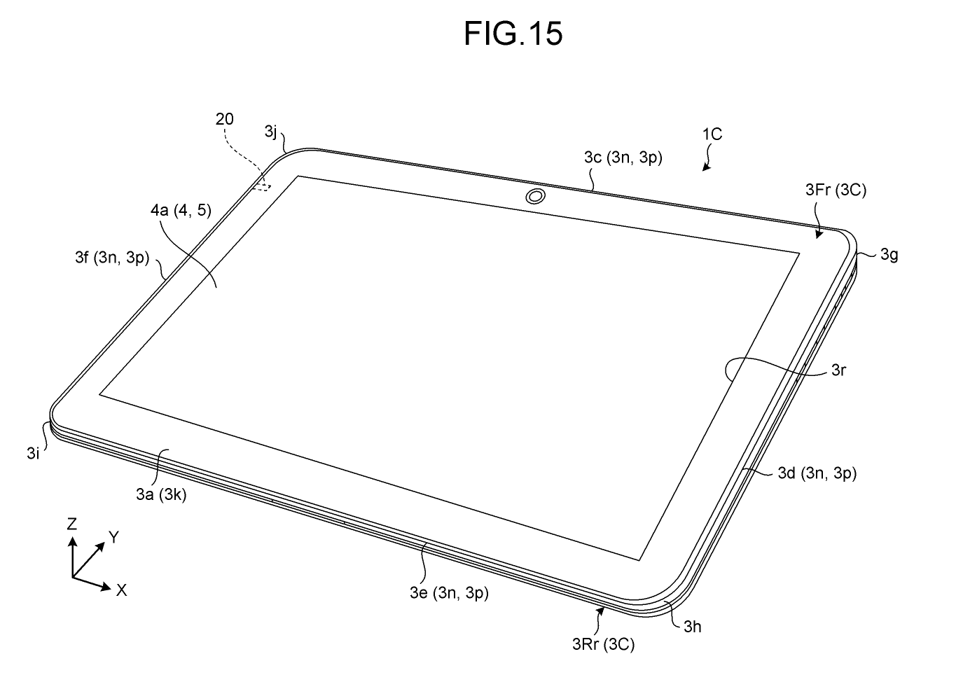

As illustrated in FIG. 15, a housing 3C of the electronic device 1C has an appearance of a quadrangular shape (a rectangular shape as an example, in the embodiment) viewed from the front or the back, for example, in the fourth embodiment. The housing 3C has a rectangular parallelepiped shape that is thin and flat in the front and back direction (the thickness direction of the housing 3C, Z direction). The housing 3C comprises a face 3a (a front face, a front face portion) and a face 3b (a back face, a back face portion) located opposite the face 3a. The face 3a and the face 3b are provided nearly side by side (in parallel as an example, in the embodiment). The housing 3A comprises four ends 3c to 3f (sides, edges) and four corners 3g to 3j (pointed portions, bent portions, ends) viewed from the front. The ends 3c and 3e are examples of long sides. The ends 3d and 3f are examples of short sides.

The housing 3C comprises the wall 3k (a part, a plate, a frame, a front wall, a front face wall, a top wall) comprising the face 3a, and the wall 3m (a part, a plate, a back wall, a rear face wall, a bottom wall, a second wall) comprising the face 3b. The walls 3k and 3m are provided respectively in a quadrangular shape (a rectangular shape as an example, in the embodiment). The housing 3C comprises four walls 3n (parts, plates, side walls, end walls, standing wall, surrounding portions, first walls) each comprising a face 3p (a side face, a surrounding face) across the wall 3k and the wall 3m. The opening 3r in a quadrangular shape is provided on the wall 3k.

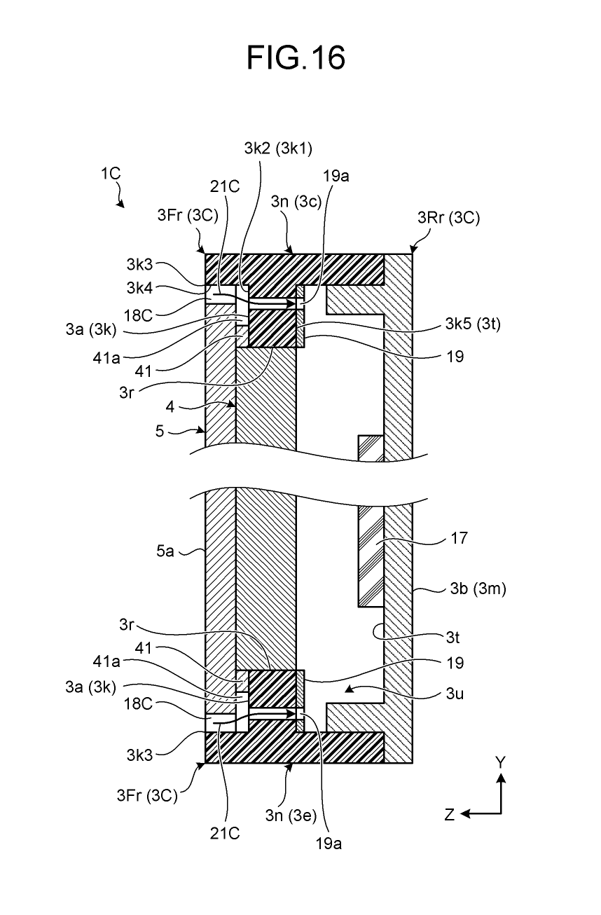

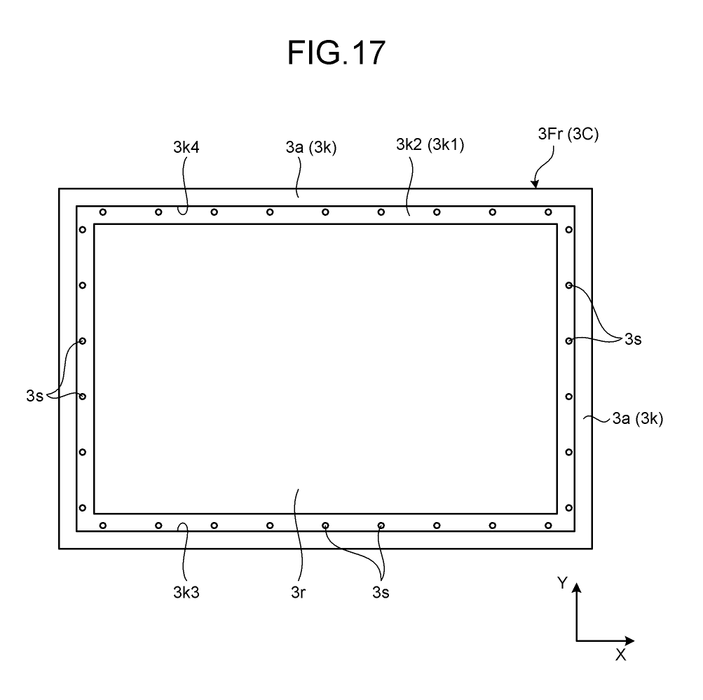

As illustrated in FIGS. 16 and 17, a recessed portion 3k1 is provided on the face 3a of the wall 3k, for example, in the fourth embodiment. The recessed portion 3k1 is provided so as to be recessed toward the wall 3m. The recessed portion 3k1 comprises a bottom face 3k2 and a face 3k4 (a surrounding face) extended from the bottom face 3k2 to an opening edge 3k3 of the recessed portion 3k1. The opening edge 3k3 of the recessed portion 3k1 also serves as an opening edge of the opening 3r. In the recessed portion 3k1, the opening 3r (a through hole) is provided therethrough and the bottom face 3k2 is provided in a circular shape. The wall 3k comprises a face 3k5 opposite the bottom face 3k2 of the recessed portion 3k1. The face 3k5 forms the inner face 3t of the housing 3C.

The housing 3C can comprise a plurality of components (segments, members) combined with each other. The housing 3C comprises the first member 3Fr (a first part, a front side member, a cover, a bezel, a frame) comprising at least the wall 3k, and the second member 3Rr (a second part, a back side member, abase, a bottom, a plate) comprising at least the wall 3m. The wall 3n is configured as a portion of the first member 3Fr, for example, in the fourth embodiment.

The first member 3Fr is made of a synthetic resin material (an electric insulator material), for example. The second member 3Rr is made of a metallic material, for example, in the fourth embodiment. According to the fourth embodiment, therefore, weight saving and improvement of stiffness and strength of the housing 3C are likely to be compatible with each other. The combination of these materials (quality of materials) is only an example; therefore, combination of other materials can be used. For example, the second member 3Rr can also be made of a synthetic resin material.

As illustrated in FIGS. 15 and 16, the display device 4 (a display module, a display, a panel, a display component), for example, is housed in the housing 3C in the fourth embodiment. Specifically, a display screen 4a located on the face 3a side of the display device 4 is exposed to the front (outside) of the housing 3C through the opening 3r. Users can visually recognize the display screen 4a from the front side of the display device 4 through the opening 3r. The display device 4 has an appearance of a quadrangular shape (a rectangular shape as an example, in the embodiment), viewed from the front of display device 4. The display device 4 has a rectangular parallelepiped shape that is thin and flat in the front and back direction. The display device 4 is a liquid crystal display (LCD), an organic electro-luminescent display (OELD), and a plasma display panel (PDP), for example.

In the fourth embodiment, on the front side (a front side, the wall 3k side) of the display device 4, the input operating panel 5 is provided, which is transparent and relatively thin in a quadrangular shape. The input operating panel 5 is a capacitance type touch panel, for example, in the fourth embodiment. The input operating panel 5 comprises an operation face 5a touched for operation (operated) by an operator.

In the fourth embodiment, the display device 4 and the input operating panel 5 are supported by the first member 3Fr. For example, the display device 4 is located in the recessed portion 3k1 of the wall 3k. The input operating panel 5 is located in the recessed portion 3k1 with its face opposite from the operation face 5a placed over the display screen 4a. The operation face 5a is exposed from the opening 3r. The input operating panel 5 is adhered (coupled, fixed) to the bottom face 3k2 of the recessed portion 3k1 with a double-faced adhesive tape 41 (a connecting portion, a tape, an adhesive member). That is to say, the double-faced adhesive tape 41 is interposed between the input operating panel 5 and the bottom face 3k2. The input operating panel 5 is attached to the wall 3k (the housing 3C) with the double-faced adhesive tape 41, with a gap 18C interposed between the input operating panel 5 and the face 3k4 of the recessed portion 3k1. The input operating panel 5 is an example of a component exposed to the outside of the housing 3C in the fourth embodiment. The wall 3k is an example of a wall provided on the housing 3C comprising the bottom face 3k2 (a face) facing the gap 18C in the fourth embodiment. The first member 3Fr is an example of a housing member made of a synthetic resin material and provided with the gap 18C interposed between itself and the input operating panel 5. For convenience of illustration, the gap 18C is magnified in FIG. 16.

As illustrated in FIGS. 16 and 17, the through hole 3s is provided on the wall 3k (the recessed portion 3k1), for example, in the fourth embodiment. A plurality of through holes 3s are provided, for example. The through holes 3s are provided with respective intervals provided therebetween, surrounding the input operating panel 5. The through holes 3s open to an inner portion 3u of the housing 3C (an inner space, a housing chamber, a chamber) and a later-described opening 41a of the double-faced adhesive tape 41. The through holes 3s communicate the gap 18C and the inner portion 3u of the housing 3C with each other through the opening 41a. The through holes 3s penetrates through the bottom face 3k2 and a face 3k5 of the wall 3k. The cross-sectional face of each of the through holes 3s is a circle, for example. The cross-sectional face of each of the through holes 3s may have other shapes such as a long-hole shape, an oval, and a polygon.

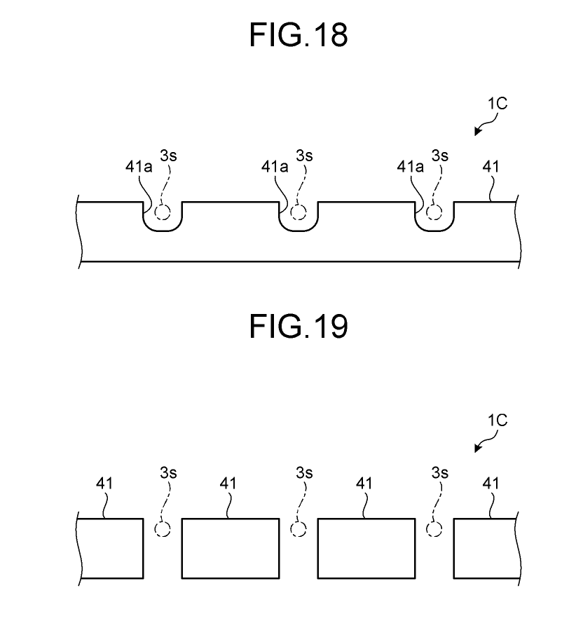

As illustrated in FIGS. 16 and 18, an opening 41a communicating with the gap 18C is provided on the double-faced adhesive tape 41, for example. The opening 41a is a cutout, for example. The opening 41a may be a through hole. A plurality of openings 41a are provided corresponding to the respective through holes 3s. The openings 41a communicate with the corresponding through holes 3s.

As illustrated in FIG. 16, the electrical conductor 19 (a conductive layer, a conductive film, a metallic layer, a metallic film, a metallic portion) is provided on the inner face 3t of the housing 3C comprising the face 3k5 of the wall 3k, for example, in the fourth embodiment. The electrical conductor 19 is provided in a sheet shape. Specifically, the electrical conductor 19 may be made of a metallic sheet (a sheet), and fixed to the inner face 3t by adhesion, for example, in the embodiment. The electrical conductor 19 may be provided by sputtering in the same manner as the embodiments described above. The electrical conductor 19 contacts the inner face 3t of the housing 3C. The electrical conductor 19 is provided to face the through hole 3s, for example. A through hole 19a is provided in the electrical conductor 19 and communicates with the through hole 3s. The electrical conductor 19 is provided partially on the inner face 3t, for example. The electrical conductor 19 may be provided entirely on the inner face 3t. The electrical conductor 19 is made of a conductive material and thus has electric conductivity. The conductive material is a metallic material such as aluminum, for example.

The electrical conductor 19 is electrically connected to an ground terminal 20 (refer to FIG. 15) of the power source terminal connected to the external power cable, for example. The ground terminal 20 is an example of a reference electric-potential point (an earth part). The electrical conductor 19 is electrically connected to the ground terminal 20 through a conductive member, for example. In the fourth embodiment, the electrical conductor 19 can also be electrically connected to a ground pin of the connector of the battery housed in the housing 3C. The ground pin is an example of a reference electric-potential point (an earth part). The electrical conductor 19 is electrically connected to the ground pin through a conductive member, for example. If the power source terminal is not connected to the external power cable, the static electricity moves to the earth pin, in the fourth embodiment.

A plurality of components (elements, electronic parts, electrical parts) such as a circuit board 17 are housed at the back side of (the rear side of, the back rear side of, the wall 3m side of, the opposite side to) the display device 4 in the housing 3C, for example, in the fourth embodiment. The components mounted on the circuit board 17 (a board, a control board, a main board, an electrical part) configures at least a portion of a control circuit (not illustrated). The control circuit may comprise an image signal processing circuit, a tuner, a high-definition multimedia interface (HDMI) (registered trademark) signal processor, an audio video (AV) input port, a remote control signal receiver, a controller, a selector, an on-screen display interface, a storage (e.g., a read only memory (ROM), a random access memory (RAM), a hard disk drive (HDD)), an audio signal processing circuit, for example. The control circuit controls output of images (moving images and still images) on the display screen 4a of the display device 4, output of audio by a speaker (not illustrated), and light emitted by a light emitting diode (LED) (not illustrated). The display device 4, the speaker, and the LED are examples of output parts. The display device 4 is electrically connected to the circuit board 17.

In addition to the circuit board 17, the followings are housed in a housing 3, for example, in the fourth embodiment: a battery (a cell, a battery pack), a camera module (a camera unit, a camera assembly, an image capturing device), a speaker module (a speaker unit, a speaker assembly, an audio output device), a connector module (a connector unit, a connector assembly, a connector device), an antenna module (an antenna unit, an antenna assembly, an antenna device), a vibration generator (a motor with an eccentric weight on its rotating shaft), and so on. These electrical parts are respectively electrically connected to the circuit board 17 and other electrical parts through a wire (e.g., a cable, a flexible cable, a flexible printed-wiring board).

In the electronic device 1C structured as described above, the static electricity that has accumulated on the operation face 5a (FIG. 16) of the input operating panel 5 moves toward the gap 18A enters the gap 18A, and then through the through holes 3s to the electrical conductor 19, for example. In other words, the through holes 3s function as a guiding path (a leading path) guiding (leading) the static electricity to the electrical conductor 19, in the fourth embodiment. An arrow 21C illustrated in FIG. 16 schematically represents an example of moving paths of the static electricity. The static electricity that has moved to the electrical conductor 19, then moves to the ground terminal 20 or the ground pin, in the fourth embodiment.

As described above, the through hole 3s is provided on the face 3k2 facing the gap 18C between the housing 3C and the input operating panel 5 and communicates the gap 18C and the inner portion 3u of the housing 3C with each other; and the electrical conductor 19 is provided contacting the inner face 3t of the housing 3C in the fourth embodiment. According to the fourth embodiment, therefore, the static electricity that has accumulated on the operation face 5a of the input operating panel 5 moves to the electrical conductor 19 through the gap 18C and the through holes 3s, thereby eliminating the static electricity from the operation face 5a, for example. According to the fourth embodiment, therefore, influence on the input operating panel 5 by the static electricity can be reduced, for example.

### Fifth Embodiment

As illustrated in FIG. 19, the double-faced adhesive tape 41 of the electronic device 1C is different from the fourth embodiment, for example, in a fifth embodiment. Other parts of the electronic device 1C in the fifth embodiment are the same as the fourth embodiment. In the fifth embodiment, a plurality of pieces of the double-faced adhesive tape 41 are provided with respective intervals provided therebetween. The through holes 3s are exposed between the adjacent pieces of double-faced adhesive tape 41.

In the electronic device 1C according to the fifth embodiment described above, similar advantageous effects to the electronic device 1C according to the fourth embodiment can be achieved.

As described above, influence on the television receiver 1A, the electronic device 1B, the electronic device 1C by the static electricity can be further reduced according to the embodiment.

While certain embodiments have been described, these embodiments have been presented by way of example only, and are not intended to limit the scope of the invention. Indeed, the embodiments described herein may be embodied in a variety of other forms; furthermore, various omissions, substitutions, combinations and changes described herein may be made without departing from the spirit of the invention. The accompanying claims and their equivalents are intended to cover such forms or modifications as would fall within the scope and spirit of the invention. The structures and the shapes of the embodiments can be partially substituted. Moreover, specifications (a structure, a type, a direction, a shape, a size, a length, a width, a thickness, a height, the number, an arrangement, a position, a material, and the like) of each of the components or the shapes can be changed appropriately.

Moreover, the various modules of the systems described herein can be implemented as software applications, hardware and/or software modules, or components on one or more computers, such as servers. While the various modules are illustrated separately, they may share some or all of the same underlying logic or code.

What is claimed is:

1. A television receiver comprising:
a first housing;
a component exposed to the outside of the first housing with a gap between the component and the first housing;
a wall with a face facing the gap, comprising an opening, the gap connecting to inside of the first housing through the opening; and
an electrical conductor on an inner face of the first housing.

2. The television receiver of claim 1, further comprising a first electrical component comprising a conductive portion and coupled to the first housing, wherein
the opening is configured to be opened with respect to the gap at a position located on a way toward the conductive portion from an end of the gap facing the outside of the first housing, and
a first spatial distance between the end and the electrical conductor is shorter than a second spatial distance between the end and the conductive portion.

3. The television receiver of claim 2, further comprising a holding portion configured to hold the first electrical component in the first housing, wherein
the component is a cover member configured to cover the first electrical component.

4. The television receiver of claim 2, further comprising a second electrical component housed in the first housing, wherein
the first electrical component comprises:
the conductive portion configured to be connected to the second electrical component wherein the first electrical component is configured to be coupled to the first housing by a second housing as the component and by a protrusion from the second housing.

5. The television receiver of claim 1, wherein the component is a touch panel.

6. The television receiver of claim 1, wherein a portion of the electrical conductor is provided in the opening.

7. The television receiver of claim 1, wherein the opening comprises an enlarged diameter portion with a diameter configured to increase toward an end on an inner side of the first housing in the opening.

8. The television receiver of claim 1, wherein the electrical conductor is provided in a layered manner.

9. The television receiver of claim 8, wherein the electrical conductor is provided by sputtering.

10. The television receiver of claim 1, wherein the electrical conductor is configured to adhere on the inner face.

11. The television receiver of claim 1, wherein the first housing comprises a housing member made of a synthetic resin material and provided with the gap interposed between the housing member and the component.

12. The television receiver of claim 1, wherein the electrical conductor is configured to be electrically connected to a reference electric-potential point.

13. An electronic device comprising:
a housing comprising;
a component with a gap between the housing and the component, the component exposed to outside of the housing;
a wall with a face facing the gap, comprising an opening in the face, the gap connecting to inside of the housing through the opening; and
an electrical conductor on an inner face of the housing.
